(19) United States
(12) Patent Application Publication
(10) Pub. No.: US 2023/0187537 A1
(43) Pub. Date: Jun. 15, 2023

(54) METHOD OF FORMING POWER SEMICONDUCTOR DEVICE

(71) Applicant: PANJIT INTERNATIONAL INC., Kaohsiung (TW)

(72) Inventors: Sang-Su Woo, Zhubei (TW); Sang-Yong Lee, Zhubei (TW)

(21) Appl. No.: 17/529,231

(22) Filed: Nov. 17, 2021

(51) Int. Cl. H01L 29/66; H01L 29/06; H01L 29/78

(52) U.S. Cl. CPC H01L 29/66734; H01L 29/0615; H01L 29/7811

(57) ABSTRACT

A method of forming a power semiconductor device is provided. The method includes the step of providing a semiconductor substrate. The semiconductor substrate has an active region and a termination region surrounding the active region. An epitaxial layer is disposed on the semiconductor substrate. The etching process is conducted to the epitaxial layer to form a first trench and a second trench. The first trench is disposed at the active region and the second trench is disposed at the termination region. A second trench width of the second trench is less than a first trench width of the first trench. An oxidation process is conducted to form a dielectric structure. The dielectric structure has a first dielectric layer disposed on the first trench and a dielectric area fully covers a trench area of the second trench.

### BACKGROUND OF THE INVENTION

### 1. Field of the Invention

The present invention generally relates to a method of forming a power semiconductor device, and in particular, to the trench area at the termination region of the power semiconductor device fully covered with a dielectric structure and the method of forming the same.

### 2. Description of the Related Art

The power semiconductor device includes insulated gate bipolar transistor (IGBT) device and metal oxide semiconductor field effect transistor (MOSFET) device. These devices may be used for the power management, like some power controller, switch circuit, power supply device and so on. The power semiconductor device is designed to withstand high voltage. Thus, the active element may drive with high current. To prevent voltage breakdown or channel effect occurred in the power semiconductor device, the device may use termination structure to avoid the above problems.

In the conventional power semiconductor device, the termination structure usually surrounds the active element with local oxidation of silicon or shield electrode. However, the conventional termination structure has many shortcomings. The local oxidation of silicon must form some doping regions to slow down the high electric field. The additional ion implantation process is required and the manufacturing process may become more complicated. Forming the shield electrode in the trench as the guarding structure may provide another solution to the termination structure. However, the shield electrode needs enough width, depth or length to achieve the desired performance. These characteristics are easily affected by the process variation when forming the shield electrode. Therefore, the conventional manufacturing process still has some considerable problems.

As the design of the electronic devices gets smaller and smaller, the power semiconductor device may have size restrictions. When using the shield electrode as the termination structure, the peripheral area may not have enough space to dispose such electrode structure. The size issue may become the considerable problems of forming the power semiconductor device.

In summary, the conventional manufacturing method to the power semiconductor device still has considerable problems. Hence, the present disclosure provides the method of forming the power semiconductor device to resolve the shortcomings of conventional technology and promote industrial practicability

### SUMMARY OF THE INVENTION

In view of the aforementioned technical problems, the primary objective of the present disclosure is to provide a method of forming a power semiconductor device, which is capable of keeping the high breakdown voltage to the power semiconductor device with smaller device profile.

In accordance with one objective of the present disclosure, a method of forming a power semiconductor device is provided. The method includes the following steps of: providing a semiconductor substrate, the semiconductor substrate has an active region and a termination region surrounding the active region; disposing an epitaxial layer on the semiconductor substrate; etching the epitaxial layer to form a first trench and a second trench, the first trench is disposed at the active region and a junction region between the active region and the termination region, and the second trench is disposed at the termination region, wherein a second trench width of the second trench is less than a first trench width of the first trench; conducting an oxidation process to form a dielectric structure, the dielectric structure has a first dielectric layer disposed on the first trench and a dielectric area fully covers a trench area of the second trench.

Preferably, the method may further include the following steps of: disposing a shield electrode in a trench space formed by the first dielectric layer and etching the shield electrode at the active region; conducting an oxide deposition to form a second dielectric layer covering the shield electrode; etching the second dielectric layer at the active region and disposing a gate electrode on the first trench at the active region; forming a doped region between the gate electrode; conducting an oxide deposition to form a third dielectric layer covering the active region and the termination region; forming a metal layer on the third dielectric layer, the metal layer contacts the doped region through a contact hole.

Preferably, the dielectric area may have a pattern shape at bottom of the dielectric area and the pattern shape corresponds to a bottom shape of the second trench.

Preferably, the pattern shape may include a continuous wave shape or a continuous ripple shape.

Preferably, the first trench width may be around 1.2-1.5 µm and the second trench width may be around 0.9-1.1 µm.

Preferably, the first trench may have a first trench depth and the second trench may have a second trench depth, the second trench depth is less than the first trench depth.

Preferably, the first trench depth and the second trench depth may be around 1-50 µm.

Preferably, the termination region may have a termination length and the termination length is around 1-200 µm.

Preferably, the dielectric area may include silicon dioxide.

Preferably, the epitaxial layer may be N-type lightly doped layer and the doped region may be N-type highly doped region.

In accordance with one objective of the present disclosure, a method of forming a power semiconductor device is provided. The method includes the following steps of: providing a semiconductor substrate, the semiconductor substrate having an active region, a termination region adjacent to the active region and a trench ring region surrounding the active region and the termination region; disposing an epitaxial layer on the semiconductor substrate; etching the epitaxial layer to form a first trench, a second trench and a third trench, the first trench being disposed at the active region and a junction region between the active region and the termination region, the second trench being disposed at the termination region, and the third trench being disposed at the trench ring region, wherein a second trench width of the second trench is less than a first trench width of the first trench; conducting an oxidation process to form a dielectric structure, the dielectric structure having a first dielectric layer disposed on the first trench and the third trench, and a dielectric area fully covering a trench area of the second trench.

Preferably, the method may further include the following steps of: disposing a shield electrode in a first trench space and a second trench space, the first trench space being formed by the first dielectric layer at the first trench and the second trench space being formed by the first dielectric layer at the third trench; etching the shield electrode at the active region; conducting an oxide deposition to form a second dielectric layer covering the shield electrode; etching the second dielectric layer at the active region and disposing a gate electrode on the first trench at the active region; forming a doped region between the gate electrode; conducting an oxide deposition to form a third dielectric layer covering the active region, the termination region and the trench ring region; forming a metal layer on the third dielectric layer, the metal layer contacting the doped region through a contact hole.

Preferably, the dielectric area may have a pattern shape at bottom of the dielectric area and the pattern shape corresponds to a bottom shape of the second trench.

Preferably, the pattern shape may include a continuous wave shape or a continuous ripple shape.

Preferably, the first trench width may be around 1.2-1.5 µm and the second trench width may be around 0.9-1.1 µm.

Preferably, a third trench width of the third trench may be less than the first trench width, the third trench width may be around 0.9-1.1 µm.

Preferably, the first trench may have a first trench depth, the second trench may have a second trench depth, and the third trench may have a third trench depth, the second trench depth is less than the first trench depth or the third trench depth.

Preferably, the first trench depth and the second trench depth may be around 1-50 µm.

Preferably, the termination region may have a termination length and the termination length is around 1-200 µm.

Preferably, the dielectric area may include silicon dioxide.

As mentioned previously, the method of forming the power semiconductor device in accordance with the present disclosure may have one or more advantages as follows.

1. The method of forming the power semiconductor device is capable of sustaining the breakdown voltage by the fully covered dielectric area at the termination region, so as to improve the robustness of sustaining electric field in the termination region of the power semiconductor device.

2. The method of forming the power semiconductor device may reduce the termination length of the power semiconductor device and therefore reduce the overall size of the power semiconductor device.

3. The method of forming the power semiconductor device may form the dielectric area by the same oxidation process without adding the additional process. The manufacturing process variation sensitivity can be reduced.

### BRIEF DESCRIPTION OF THE DRAWINGS

The technical features, detail structures, advantages and effects of the present disclosure will be described in more details hereinafter with reference to the accompanying drawings that show various embodiments of the invention as follows.

FIG. 1 is a schematic diagram of the power semiconductor device in accordance with the embodiment of the present disclosure.

FIGS. 2A to 2C are schematic diagrams of the manufacturing process of forming the power semiconductor device in accordance with the embodiment of the present disclosure.

FIG. 3 is a schematic diagram of the 3D structure of the power semiconductor device in accordance with the embodiment of the present disclosure.

FIGS. 4A to 4F are schematic diagrams of the manufacturing process of forming the power semiconductor device in accordance with the embodiment of the present disclosure.

FIG. 5 is a schematic diagram of the 3D structure of the power semiconductor device in accordance with the embodiment of the present disclosure.

FIG. 6 is a schematic diagram of the power semiconductor device in accordance with another embodiment of the present disclosure.

FIGS. 7A to 7I are schematic diagrams of the manufacturing process of forming the power semiconductor device in accordance with another embodiment of the present disclosure.

FIGS. 8A and 8B are schematic diagrams of the 3D structure of the power semiconductor device in accordance with another embodiment of the present disclosure.

### DETAILED DESCRIPTION OF THE PREFERRED EMBODIMENTS

In order to facilitate the understanding of the technical features, the contents and the advantages of the present disclosure, and the effectiveness thereof that can be achieved, the present disclosure will be illustrated in detail below through embodiments with reference to the accompanying drawings. The diagrams used herein are merely intended to be schematic and auxiliary to the specification, but are not necessary to be true scale and precise to the configuration after implementing the present disclosure. Thus, it should not be interpreted in accordance with the scale and the configuration of the accompanying drawings to limit the scope of the present disclosure on the practical implementation.

As those skilled in the art would realize, the described embodiments may be modified in various different ways. The exemplary embodiments of the present disclosure are for explanation and understanding only. The drawings and description are to be regarded as illustrative in nature and not restrictive. Similar reference numerals designate similar elements throughout the specification.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

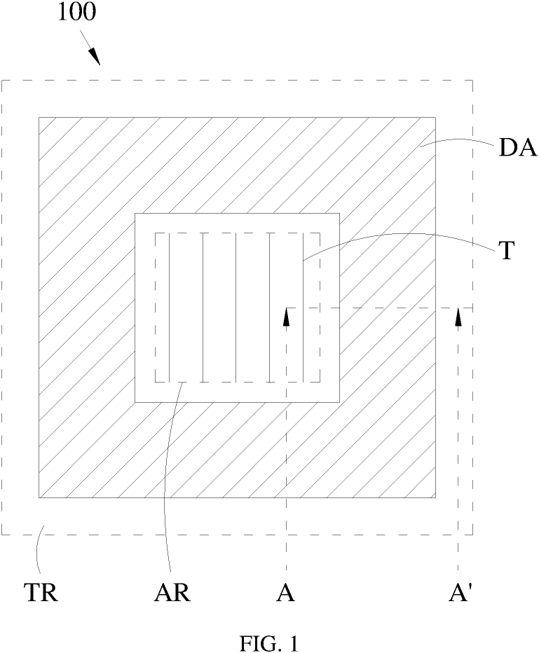

Please refer to FIG. 1, which is the schematic diagram of the power semiconductor device in accordance with the embodiment of the present disclosure. FIG. 1 shows the top view of a power semiconductor device 100. The power semiconductor device 100 includes an active region AR and a termination region TR. The termination region TR surrounds the active region AR. Since the power semiconductor device 100 is designed to withstand high voltage, the active region AR may drive with high current. To prevent voltage breakdown or other channel effect, the termination region TR is disposed around the active region AR to prevent the above effects. The termination region TR can also isolate the influence from the external components.

The active region AR includes a plurality of active trenches T. The shield electrode and the gate electrode are disposed in these active trenches T. The termination region TR may include several trenches made in the same manufacturing process of making the active trenches T. In the present disclosure, a dielectric area DA fully covers the trench area of these trenches at the termination region TR. The dielectric area DA surrounds the active region AR to sustain the electric field in the termination region TR and reduce the process variation sensitivity of breakdown voltage. The dielectric area DA is fully covered with the dielectric material, for example, silicon dioxide. The detail structure and the manufacturing method of the power semiconductor device 100 will be described in the following embodiments.

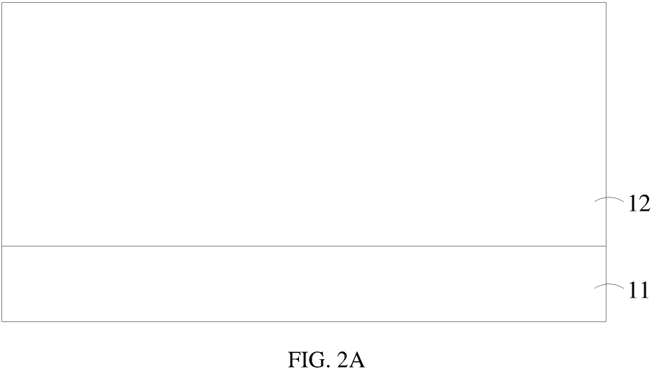

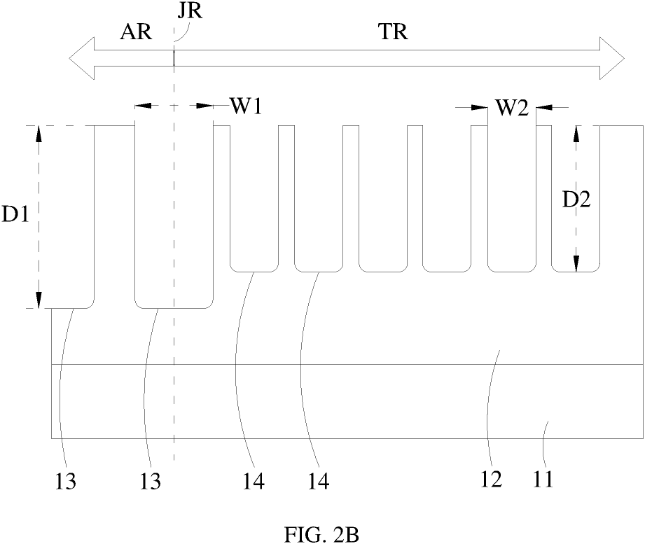

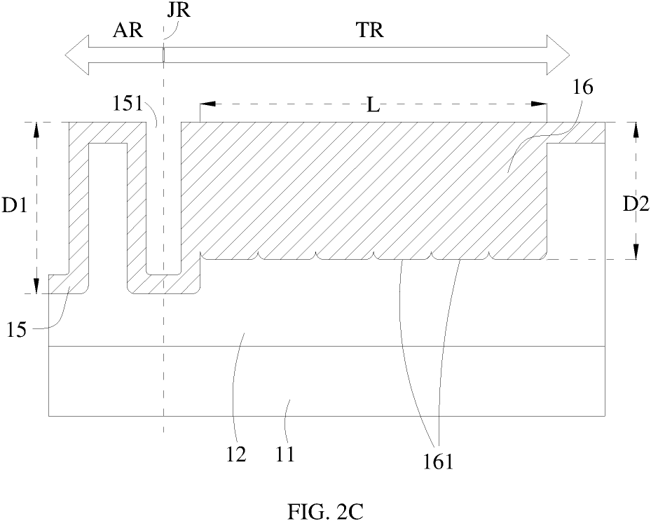

Please refer to FIG. 2A to FIG. 2C, which are the schematic diagrams of the manufacturing process of forming the power semiconductor device in accordance with the embodiment of the present disclosure. FIG. 2A to FIG. 2C show a view along the section A-A′ of FIG. 1.

In FIG. 2A, the manufacturing process provides a semiconductor substrate 11. The semiconductor substrate 11 is disposed at the active region AR and the termination region TR. The manufacturing process provides an epitaxial growth process to dispose an epitaxial layer 12 on the semiconductor substrate 11. The epitaxial layer 12 is also disposed at the active region AR and the termination region TR. The epitaxial layer 12 may have a first conductivity type, for example, an N-type lightly doped layer.

In FIG. 2B, the manufacturing process provides an etching process. In this process, a photoresist layer is disposed on the epitaxial layer 12. The photoresist layer can be a patterned layer or a stacked layer including oxide or nitride material. Using the photoresist layer as a hard mask, a plurality of trenches can be formed by etching the epitaxial layer 12. These trenches include first trenches 13 and second trenches 14. The first trenches 13 are disposed at the active region AR and a junction region JR. The junction region JR is at the location between the active region AR and the termination region TR. The second trenches 14 are disposed at the termination region TR. The numbers of the first trenches 13 and the second trenches 14 used in the present disclosure are for illustration only. The number of trenches may be changed according to the type of the power device.

The first trenches 13 include a first trench width W1 and a first trench depth D1. The second trenches include a second trench width W2 and a second trench depth D2. The second trench width W2 is less than the first trench width W1. The first trench width W1 may be around 1.2-1.5 µm and the second trench width W2 may be around 0.9-1.1 µm. In the present disclosure, the first trench width W1 of the first trench 13 may be 1.4 µm and the second width W2 of the second trench 14 may be 1.0 µm.The difference between the first trench 13 and the second trench 14 can be formed by the different patterns of the mask. Since the first width W1 is greater than the second width W2, the etching rate of the first trench 13 is quicker than the second trench 14. Therefore, the first trench depth D1 is deeper than the second trench depth D2. The first trench depth D1 and the second trench depth D2 may be around 1-50 µm.In the present disclosure, the first trench depth D1 may be 6.0 µm and the second trench depth D2 may be 4.5 µm.

In FIG. 2C, the manufacturing process provides an oxidation process to form a dielectric structure. The oxidation process may be a thermal oxidation process. During this process, the dielectric material like silicon dioxide is formed and covered the first trenches 13 and the second trenches 14. In the present disclosure, the dielectric structure has a first dielectric layer 15 disposed on the first trench 13 and a dielectric area 16 fully covers a trench area of the second trench 14. As mentioned above, the first trench width W1 and the second width W2 are different. In the active region AR, the surface of the first trenches 13 is covered by the dielectric material to form the first dielectric layer 15. There is still a trench space 151 in the first trenches 13 and the trench space 151 is formed by the first dielectric layer 15. In the termination region TR, the second trench 14 has smaller trench width. The full trench area may be filled with the dielectric material to form the dielectric area 16. In the present disclosure, the dielectric area 16 may be a fully oxidized trench area. The dielectric area 16 has a pattern shape 161 at bottom of the dielectric area 16 and the pattern shape 161 corresponds to a bottom shape of the second trench 14. The pattern shape 161 is naturally formed by the oxidation process. Based on the second trench width W2 or the distance between two second trenches 14, the pattern shape 161 may be a continuous wave shape or a continuous ripple shape.

The manufacturing process of forming the dielectric structure is the same oxidation process of forming the dielectric layer at the active region AR. The dielectric area 16 at the termination region TR does not require the additional process. Therefore, the manufacturing process can be simplified and the process variation can be reduced.

The power semiconductor device includes the fully oxidized dielectric area 16 at the termination region TR. The termination length L of the termination region TR is around 1-200 µm. In the present disclosure, the termination length L may be 10 µm.This termination length L is only half of the length in the conventional structure. Based on such structure, the area for disposing the termination region TR can be reduced. The size of the power semiconductor device can be reduced accordingly.

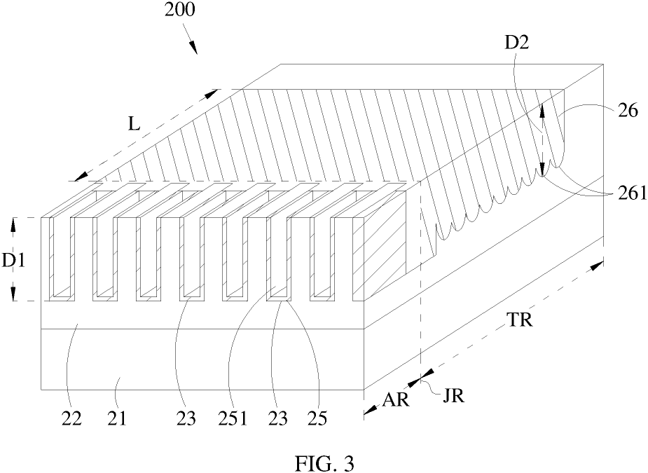

Please refer to FIG. 3, which is the schematic diagram of the 3D structure of the power semiconductor device in accordance with the embodiment of the present disclosure. As shown in the figure, the power semiconductor device 200 includes a semiconductor substrate 21 and an epitaxial layer 22 disposed on the semiconductor substrate 21. The semiconductor substrate 21 can be made by semiconductor compound. The epitaxial layer 22 may be an N-type lightly doped layer. The power semiconductor device 200 is divided to two regions. That is, an active region AR and a termination region TR. The termination region TR surrounds the active region AR to prevent the voltage breakdown or other channel effect.

The active region AR includes a plurality of first trenches 23, which are disposed at the active region AR and a junction region JR between the active region AR and the termination region TR. A first dielectric layer 25 is disposed on the surface of the first trenches 23. The dielectric layer 25 covers the sidewall surface and the bottom surface of the first trenches 23, and a trench space 251 is formed by the first dielectric layer 25 in the first trench 23. The trench space may be used to dispose the shield electrode and the gate electrode. The detail structure of the above electrode will be described in the following embodiments.

In the termination region TR, a plurality of second trenches may be formed by the same manufacturing process of forming the first trenches 23. The first trench may have a first trench width and the second trench may have a second trench width, the second trench width is less than the first width. Due to the difference of the trench width, the full area of the second trenches is filled with the dielectric material, liked silicon dioxide, to form a dielectric area 26. The dielectric area 26 has a pattern shape 261 at bottom of the dielectric area 26. The pattern shape 261 is formed by the oxidation process and the pattern shape 261 corresponds to a bottom shape of the second trench. The pattern shape 261 may include be a continuous wave shape or a continuous ripple shape. The dielectric area 26 at the termination region TR is formed by the same oxidation process of forming the dielectric layer at the active region AR. The dielectric area 26 does not require the additional process. The size variation occurred in the manufacturing process can be reduced.

The first trench has a first trench depth D1 and the second trench has a second trench depth D2. The depth of the dielectric area 26 is based on the second trench depth D2. The second trench depth D2 is less than the first trench depth D1. The first trench depth D1 and the second trench depth D2 may be around 1-50 µm.In the present disclosure, the first trench depth D1 may be 6.0 µm and the second trench depth D2 may be 4.5 µm.The termination region TR may have a termination length L and the termination length L is determined by the structure of the dielectric area 26. The termination length L is around 1-200 µm. In the present disclosure, the termination length L may be 10 µm. The narrow termination length L is able to reduce the area needed for the termination region. Therefore, the material used for forming the power semiconductor device 200, like the material for forming the substrate layer 21 and the epitaxial layer 22, can be reduced, and the manufacturing cost can be reduced accordingly.

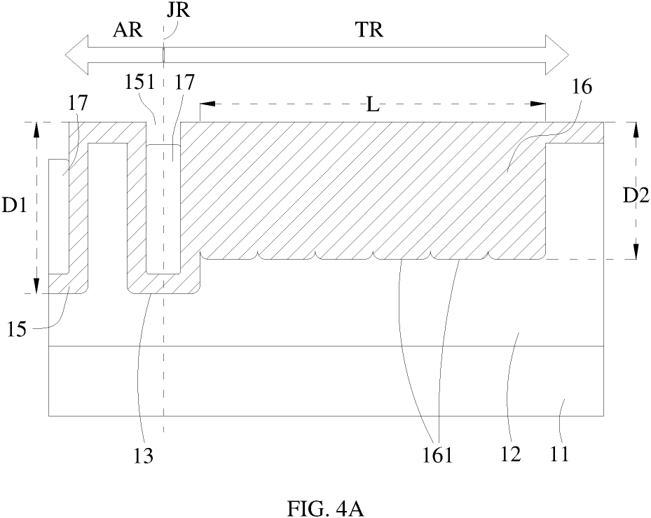

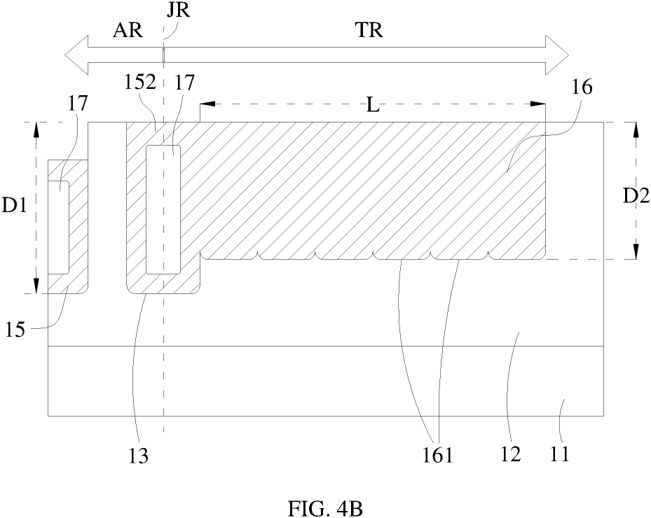

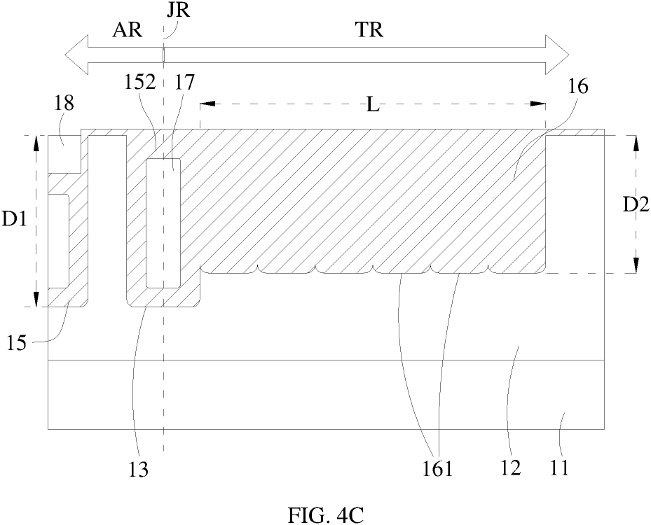

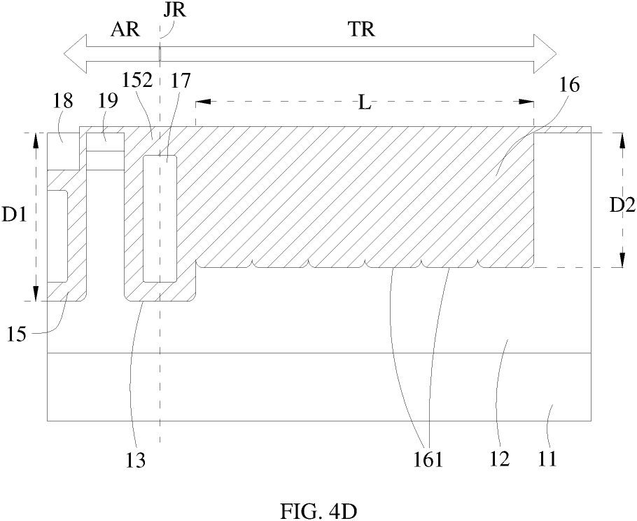

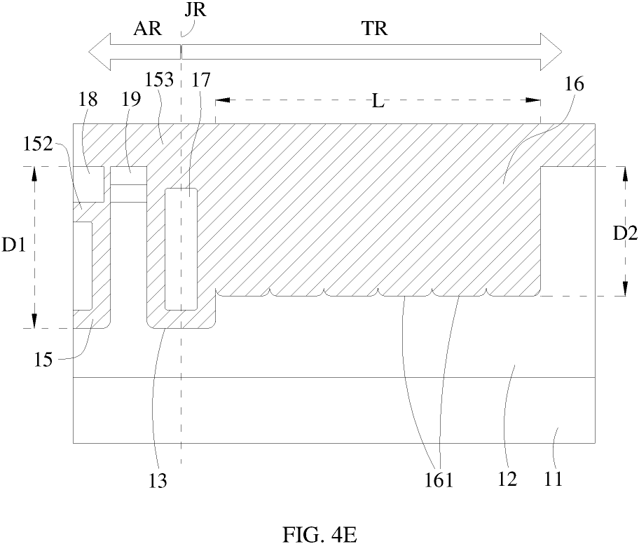

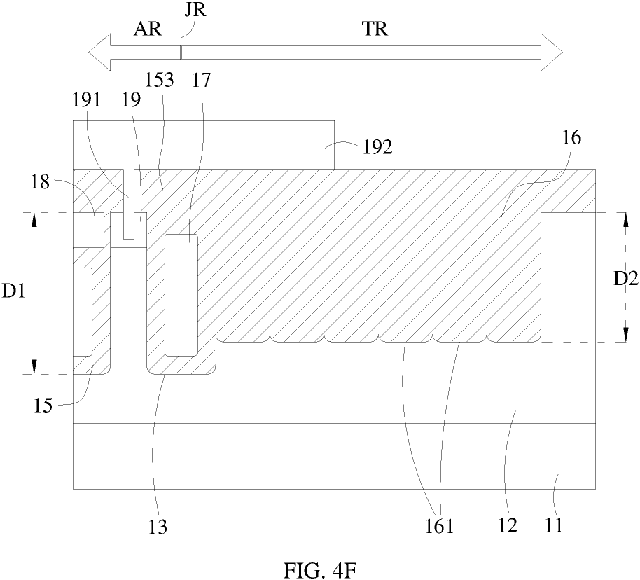

Please refer to FIG. 4A to FIG. 4F, which are the schematic diagrams of the manufacturing process of forming the power semiconductor device in accordance with another embodiment of the present disclosure. FIG. 4A to FIG. 4F are the manufacturing process of forming the active region. The manufacturing process may also include the process described in FIG. 2A to FIG. 2C, the same numeral numbers refer the same elements and the same content will not be repeated again.

In FIG. 4A, the manufacturing process disposes a shield electrode in the trench space 151. As mentioned in FIG. 2C, the trench space 151 is formed in the first trench 13 at the active region AR and the junction region JR. A conductive structure is formed in the trench space 151. The manufacturing process includes a deposition process to form a shield electrode 17 in the trench space 151. The shield electrode 17 includes a poly electrode. An anisotropy etching is conducted to the shield electrode 17. The shield electrode 17 at active region AR is further etched to create a space for forming a gate electrode.

In FIG. 4B, the manufacturing process conducts an oxide deposition to form a second dielectric layer covering the shield electrode. The trench space 151 at the active region AR and the junction region JR are covered with oxidized layer to form the second dielectric layer 152. The oxidized material, like silicon dioxide is filled in the trench space 151, so as to cover the shield electrode 17 at the active region AR and the junction region JR.

In FIG. 4C, the manufacturing process conducts the etching process to the second dielectric layer 152 at the active region AR, so as to create a space to form the gate structure. Therefore, the manufacturing process disposes a gate electrode 18 in the space at the first trench 13 of the active region AR. The gate electrode 18 includes a poly electrode. The gate electrode 18 is etched back to form the gate structure.

FIG. 4D, the manufacturing process conducts implantation process to form a doped region 19 between the gate electrode 18. The doped region 19 is disposed at the top side of the epitaxial layer 12 between the gate electrodes 18. The doped region 19 is also disposed between gate electrodes 18 and the shield electrode 17. The doped region may be N-type highly doped region and a p-well channel is formed between the doped region 19 and the epitaxial layer 12.

FIG. 4E, the manufacturing process conducts another oxide deposition to form a third dielectric layer 153. The third dielectric layer 153 covers both the active region AR and the termination region TR. The third dielectric layer 153 may be the inter layer isolation layer.

FIG. 4F, the manufacturing process conducts the etching process to the third dielectric layer 153 to form a contact hole 191. The contact hole 191 contacts the doped region 19. The manufacturing process forms a metal layer 192 on the third dielectric layer 153 and filled in the contact hole 191. The metal layer 192 may be the source contact of the power semiconductor device 100. The metal layer 192 is formed by the conductive metal.

The manufacturing process described in FIG. 4A to FIG. 4F is the method of forming the active region AR. However, the present disclosure is not limited on the present embodiment. In the other embodiment, the different kinds of active region can be made by the corresponding process. These processes can be combined to the process of forming the termination region, so as to achieve the effect of the power semiconductor device with good performance and small size.

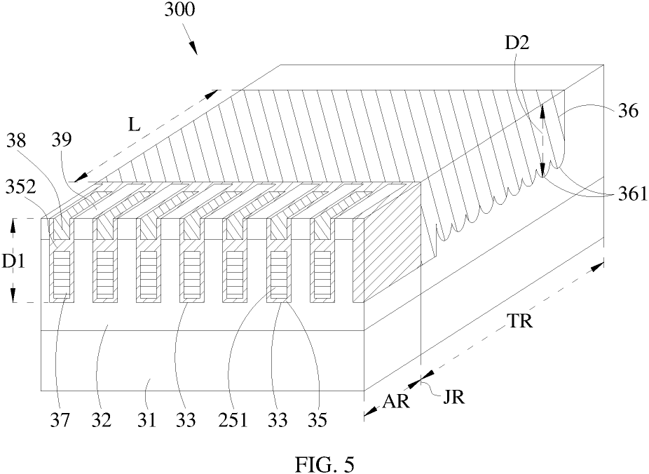

Please refer to FIG. 5, which is the schematic diagram of the 3D structure of the power semiconductor device in accordance with another embodiment of the present disclosure. As shown in the figure, the power semiconductor device 300 includes a semiconductor substrate 31 and an epitaxial layer 32 disposed on the semiconductor substrate 31. The semiconductor substrate 31 can be made by semiconductor compound. The epitaxial layer 32 may be an N-type lightly doped layer. The power semiconductor device 300 is divided to two regions. That is, an active region AR and a termination region TR. The termination region TR surrounds the active region AR to prevent the voltage breakdown or other channel effect.

The active region AR includes a plurality of first trenches 33, which are disposed at the active region AR and a junction region JR between the active region AR and the termination region TR.

In the termination region TR, the dielectric area 36 is disposed on the termination region TR. The dielectric area 36 fully covers a trench area of the second trench at the termination region TR. The dielectric area 36 has a pattern shape 361 at bottom of the dielectric area 36 and the pattern shape 361 corresponds to a bottom shape of the second trench. The pattern shape 361 may include a continuous wave shape or a continuous ripple shape.

In the active region AT, the first dielectric layer 35 is disposed on the surface of the first trenches 33. The dielectric layer 35 covers the sidewall surface and the bottom surface of the first trenches 33. The shield electrode 37 is disposed on the first dielectric layer 35 and the second dielectric layer 352 covers the shield electrode 37. The gate electrode 38 is disposed on the shield electrode 37 at the active region AR. The shield electrode 37 and the gate electrode 38 are separated by the second dielectric layer 352. The doped region 39 is disposed between the gate electrode 38. The doped region 39 may be N-type highly doped region.

The active region AR includes a plurality of first trenches 33, which are disposed at the active region AR and a junction region JR between the active region AR and the termination region TR. The termination region TR includes a plurality of second trenches formed by the same manufacturing process of forming the first trenches 33. The first trench may have a first trench width and the second trench may have a second trench width, the second trench width is less than the first width. Due to the difference of the trench width, the full area of the second trenches is filled with the dielectric material, liked silicon dioxide, to form a dielectric area 36.

The first trench has a first trench depth D1 and the second trench has a second trench depth D2. The depth of the dielectric area 36 is based on the second trench depth D2. The second trench depth D2 is less than the first trench depth D1. The first trench depth D1 and the second trench depth D2 may be around 1-50 µm. In the present disclosure, the first trench depth D1 may be 6.0 µm and the second trench depth D2 may be 4.5 µm. The termination region TR may have a termination length L and the termination length L is determined by the structure of the dielectric area 36. The termination length L is around 1-200 µm. In the present disclosure, the termination length L may be 10 µm. The narrow termination length L is able to reduce the area needed for the termination region. Therefore, the material used for forming the power semiconductor device 200 can be reduced, and the manufacturing cost can be reduced accordingly.

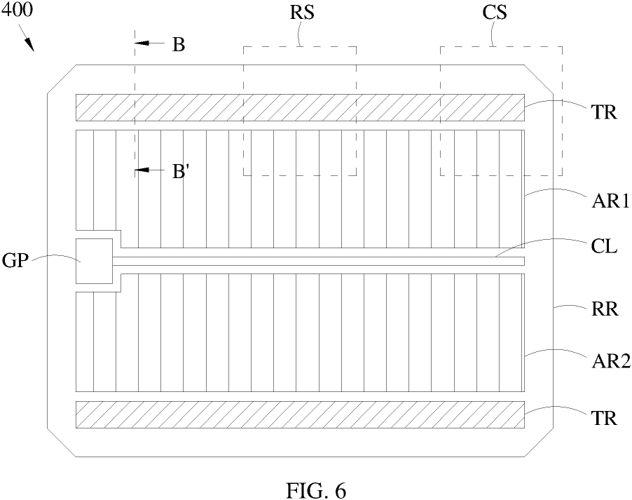

Please refer to FIG. 6, which is the schematic diagram of the power semiconductor device in accordance with another embodiment of the present disclosure. FIG. 6 shows the top view of a power semiconductor device 400. The power semiconductor device 400 includes an active region AR, a termination region TR and a trench ring region RR. The termination region TR is adjacent to the active region AR. In the present disclosure, the active region AR includes a first active region AR1 and a second active region AR2. A gate pad GP and a connection line CL are disposed between the first active region AR1 and the second active region AR2. The gate pad connects to the power source and the connection line CL connects to the metal contact at the active area AR.

The termination region TR is disposed on one side of the first active region AR1 and the other side of the second active region AR2. That is, the termination region TR covers two sides of the active region AR. Based on the same reason to prevent voltage breakdown or other channel effect, the trench ring region RR is provided. The trench ring region RR surrounds the active region AR and the termination region TR to prevent the above effects. The trench ring region RR can also isolate the influence from the external components.

The active region AR includes a plurality of active trenches T. The shield electrode and the gate electrode are disposed in these active trenches T. The termination region TR may include several trenches made in the same manufacturing process of making the active trenches T. In the present disclosure, a dielectric area DA fully covers the trench area of these trenches at the termination region TR. The trench ring region RR also includes a trench structure made in the same manufacturing process of making the active trenches T. This trench surrounds the semiconductor device as a ring shape structure.

The dielectric area DA is fully covered with the dielectric material, for example, silicon dioxide. The shield electrode will be arranged in the active trenches T and the trench structure at the trench ring region RR. The detail structure and the manufacturing method of the power semiconductor device 400 will be described in the following embodiments.

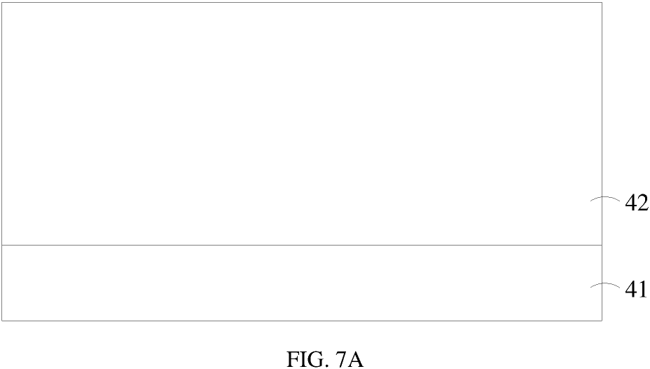

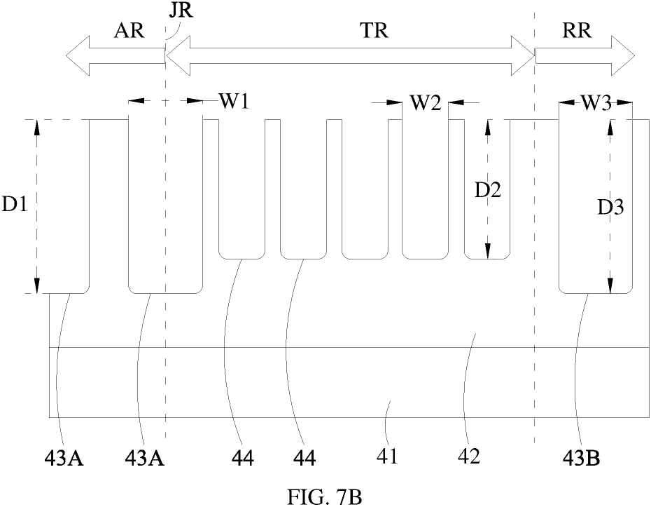

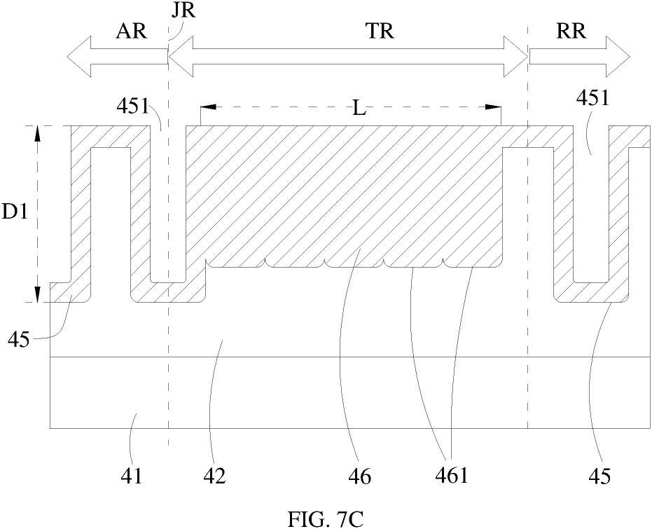

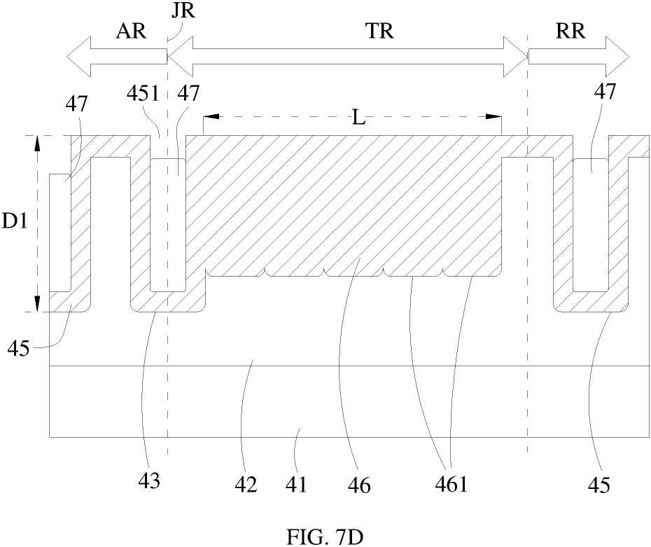

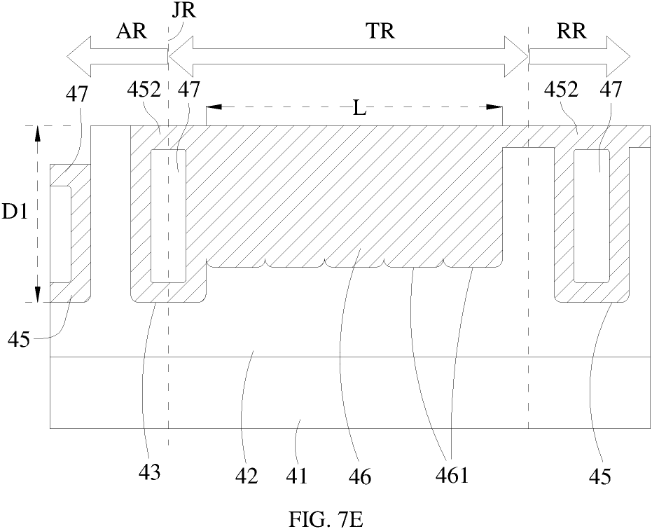

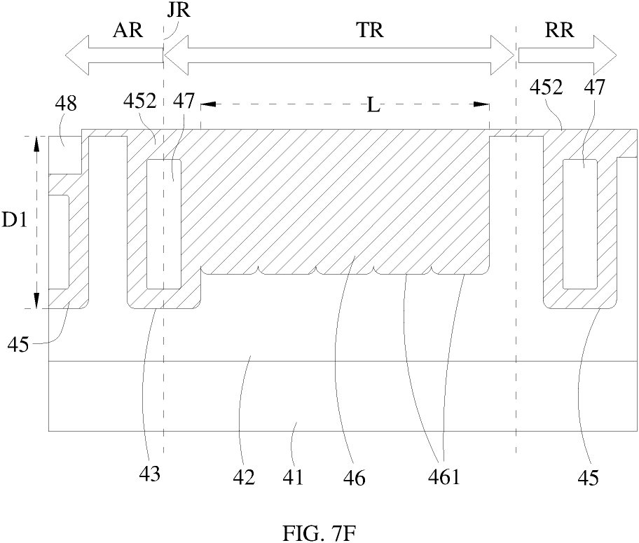

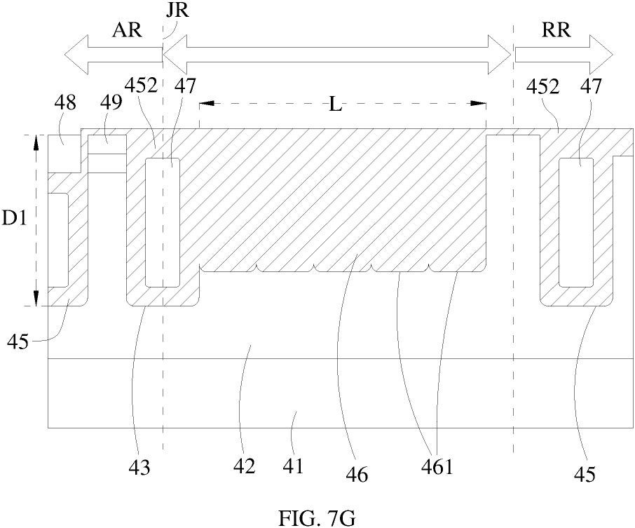

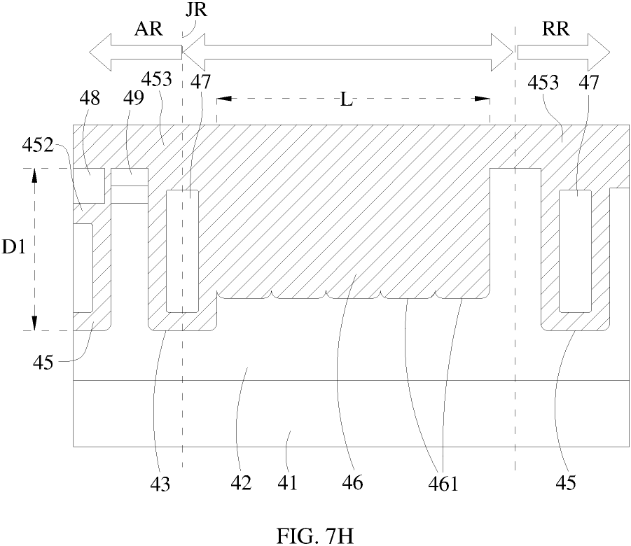

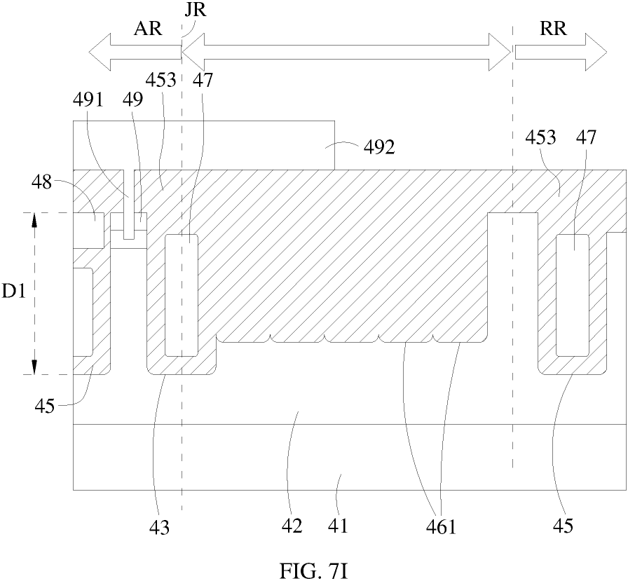

Please refer to FIG. 7A to FIG. 7I, which are the schematic diagrams of the manufacturing process of forming the power semiconductor device in accordance with another embodiment of the present disclosure. FIG. 7A to FIG. 7I show a view along the section B-B′ of FIG. 6.

In FIG. 7A, the manufacturing process provides a semiconductor substrate 41. The semiconductor substrate 41 is disposed at the active region AR, the termination region TR and the trench ring region RR. The manufacturing process provides an epitaxial growth process to dispose an epitaxial layer 42 on the semiconductor substrate 41. The epitaxial layer 42 is also disposed at the active region AR, the termination region TR and the trench ring region RR. The epitaxial layer 42 may have a first conductivity type, for example, an N-type lightly doped layer.

In FIG. 7B, the manufacturing process provides an etching process. In this process, a photoresist layer is disposed on the epitaxial layer 42. The photoresist layer can be a patterned layer or a stacked layer including oxide or nitride material. Using the photoresist layer as a hard mask, a plurality of trenches can be formed by etching the epitaxial layer 42. These trenches include first trenches 43A, second trenches 44 and third trench 43B. The first trenches 43 are disposed at the active region AR and a junction region JR. The junction region JR is at the location between the active region AR and the termination region TR. The second trenches 44 are disposed at the termination region TR. The third trench 43B is disposed at the trench ring region RR. The numbers of the first trenches 43A and the second trenches 44 used in the present disclosure are for illustration only. The number of trenches may be changed according to the type of the power device. The third trench 43B may be a single trench structure.

The first trenches 43A include a first trench width W1 and a first trench depth D1. The second trenches 44 include a second trench width W2 and a second trench depth D2. The third trench 43B includes a third trench width W3 and a third trench depth D3. The second trench width W2 is less than the first trench width W1 or the third width W3. The first trench width W1 may be around 1.2-1.5 µm. The second trench width W2 and the third width may be around 0.9-1.1 µm. The first trench depth D1 or the third trench depth D3 is deeper than the second trench depth D2. The first trench depth D1, the second trench depth D2 and the third trench depth D3 may be around 1-50 µm.

In the present disclosure, the first trench 43A and the third trench 43 B have the same size of the trench structure. The first trench width W1 and the third width W3 of the may be 1.4 µm. The first trench depth D1 and the third trench depth D3 may be 6.0 µm. The second trench 44 is smaller than the first trench 43A or the third trench 43B. The second width W2 may be 1.0 µm and the second trench depth D2 may be 4.5 µm.

In FIG. 7C, the manufacturing process provides an oxidation process to form a dielectric structure. The oxidation process may be a thermal oxidation process. During this process, the dielectric material like silicon dioxide is formed and covered the first trenches 43A, the second trenches 44, and the third trench 43B. In the present disclosure, the dielectric structure has a first dielectric layer 45 disposed on the first trench 43A and the third trench 43B, and a dielectric area 46 fully covers a trench area of the second trench 44. The surface of the first trenches 43A and the third trench 43B is covered by the dielectric material to form the first dielectric layer 45. There is still a trench space 451 in both the first trench 43A and the third trench 43B. In the termination region TR, the second trench 44 has smaller trench width. The full trench area may be filled with the dielectric material to form the dielectric area 46. In the present disclosure, the dielectric area 46 may be a fully oxidized trench area. The dielectric area 46 has a pattern shape 461 at bottom of the dielectric area 46 and the pattern shape 461 corresponds to a bottom shape of the second trench 44. The pattern shape 461 is naturally formed by the oxidation process and the pattern shape 161 may be a continuous wave shape or a continuous ripple shape.

The manufacturing process of forming the dielectric structure is the same oxidation process of forming the dielectric layer at the active region AR and the trench ring region RR. The dielectric area 46 at the termination region TR does not require the additional process. Therefore, the manufacturing process can be simplified and the process variation can be reduced. The termination length L may be 10 µm. This termination length L is only half of the length in the conventional structure. Based on such structure, the area for disposing the termination region TR can be reduced. The size of the power semiconductor device can be reduced accordingly.

In FIG. 7D, the manufacturing process disposes a shield electrode in the trench space 451. As mentioned in FIG. 7C, the trench spaces 451 are formed in the first trench 13A and the third trench 43B. A conductive structure is formed in the trench space 451. The manufacturing process includes a deposition process to form a shield electrode 47 in the trench space 451. The shield electrode 47 includes a poly electrode. An anisotropy etching is conducted to the shield electrode 47. The shield electrode 47 at active region AR is further etched to create a space for forming a gate electrode.

In FIG. 7E, the manufacturing process conducts an oxide deposition to form a second dielectric layer covering the shield electrode. The trench space 451 at the active region AR, the junction region JR and the trench ring region RR are covered with oxidized layer to form the second dielectric layer 452. The oxidized material, like silicon dioxide is filled in the trench space 451, so as to cover the shield electrode 47 at the active region AR, the junction region JR and the trench ring region RR .

In FIG. 7F, the manufacturing process conducts the etching process to the second dielectric layer 452 at the active region AR, so as to create a space to form the gate structure. Therefore, the manufacturing process disposes a gate electrode 48 in the space at the first trench 43A of the active region AR. The gate electrode 48 includes a poly electrode. The gate electrode 48 is etched back to form the gate structure.

FIG. 7G, the manufacturing process conducts implantation process to form a doped region 49 between the gate electrode 48. The doped region 49 is disposed at the top side of the epitaxial layer 42 between the gate electrodes 48. The doped region 49 is also disposed between gate electrodes 48 and the shield electrode 47. The doped region may be N-type highly doped region and a p-well channel is formed between the doped region 49 and the epitaxial layer 42.

FIG. 7H, the manufacturing process conducts another oxide deposition to form a third dielectric layer 453. The third dielectric layer 453 covers both the active region AR, the termination region TR and the trench ring region RR. The third dielectric layer 453 may be the inter layer isolation layer.

FIG. 7I, the manufacturing process conducts the etching process to the third dielectric layer 453 to form a contact hole 491. The contact hole 491 contacts the doped region 49. The manufacturing process forms a metal layer 492 on the third dielectric layer 453 and filled in the contact hole 491. The metal layer 492 may be the source contact of the power semiconductor device 400. The metal layer 492 is formed by the conductive metal.

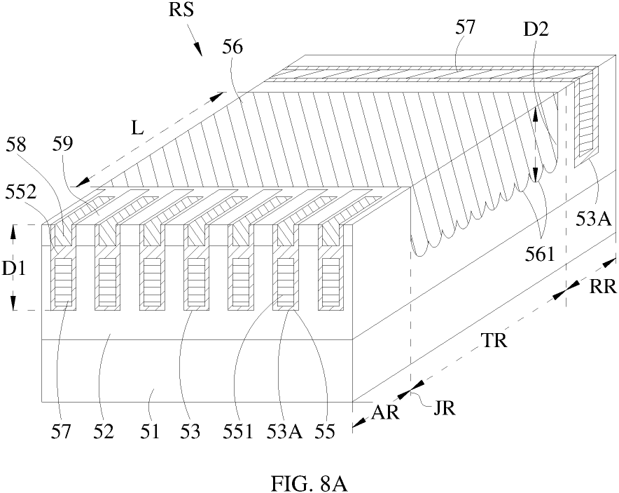

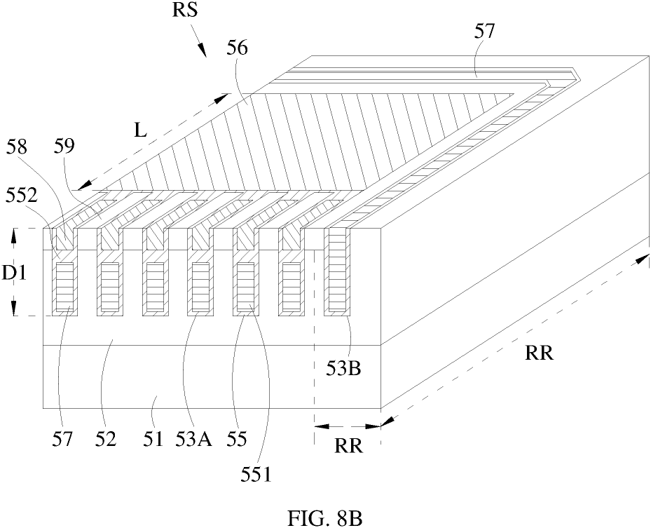

Please refer to FIG. 8A and FIG. 8B, which are the schematic diagram of the 3D structure of the power semiconductor device in accordance with another embodiment of the present disclosure. FIG. 8A shows the 3D structure of the repeated structure RS as shown in the power semiconductor device 400 of FIG. 6. FIG. 8B shows the 3D structure of the corner structure CS as shown in the power semiconductor device 400 of FIG. 6.

In FIG. 8A, the repeated structure RS includes a semiconductor substrate 51 and an epitaxial layer 52 disposed on the semiconductor substrate 51. The semiconductor substrate 51 can be made by semiconductor compound. The epitaxial layer 52 may be an N-type lightly doped layer. The repeated structure RS includes an active region AR, a termination region TR and a trench ring region RR. The termination region TR is disposed adjacent to the active region AR and the trench ring region RR covers the outer side of the termination region TR to prevent the voltage breakdown or other channel effect.

The active region AR includes a plurality of first trenches 53A, which are disposed at the active region AR and a junction region JR between the active region AR and the termination region TR.

In the termination region TR, the dielectric area 56 is disposed on the termination region TR. The dielectric area 56 fully covers a trench area of the second trench at the termination region TR. The dielectric area 56 has a pattern shape 561 at bottom of the dielectric area 56 and the pattern shape 561 corresponds to a bottom shape of the second trench. The pattern shape 561 may include a continuous wave shape or a continuous ripple shape.

The trench ring region RR includes a third trench 53B, which is similar to the first trench 53A at the active region AR. The first dielectric layer 55 is disposed on the surface of the first trenches 53A and the third trench 53B. The dielectric layer 55 covers the sidewall surface and the bottom surface of the first trenches 53A and the third trench 53B. The shield electrode 57 is disposed on the first dielectric layer 55 and the second dielectric layer 552 covers the shield electrode 57. The gate electrode 58 is disposed on the shield electrode 57 at the active region AR. The shield electrode 57 and the gate electrode 58 are separated by the second dielectric layer 552. The doped region 59 is disposed between the gate electrode 58. The doped region 59 may be N-type highly doped region.

In FIG. 8B, the corner structure CS includes the similar structure at the repeated structure RS. The corner structure CS includes an active region AR, a termination region TR and a trench ring region RR. The termination region TR is disposed adjacent to the active region AR and the trench ring region RR covers the outer side of the termination region TR to prevent the voltage breakdown or other channel effect. Since the corner structure CS is located at the corner position, the trench ring region RR surrounds the active region AR and the termination region TR.

The structures of the active region AR and the termination region TR are similar to the structures mentioned in the repeated structure RS. The active region AR includes a plurality of first trenches 53A and the shield electrode 57 and the gate electrode 58 are disposed in the first trenches. The termination region TR includes a dielectric area 56 fully covered by the dielectric material, like silicon dioxide. The dielectric area 56 has a pattern shape 561 at bottom of the dielectric area 56 and the pattern shape 561 corresponds to a bottom shape of the second trench. The pattern shape 561 may include a continuous wave shape or a continuous ripple shape. The trench ring region RR includes a third trench 53B, which is similar to the first trench 53A at the active region AR. The shield electrode 57 is disposed in the third trench 53B to form the protection ring of the device.

The active region AR includes a plurality of first trenches 53A and the trench ring region RR includes the third trench 53B. The termination region TR includes a plurality of second trenches 54 formed by the same manufacturing process of forming the first trenches 53A and the third trench 53B. The first trench 53A may have a first trench width, the second trench may have a second trench width, and the third trench 53B may have a third trench width. The second trench width is less than the first width or the third trench width. Due to the difference of the trench width, the full area of the second trenches is filled with the dielectric material, liked silicon dioxide, to form a dielectric area 56.

The first trench has a first trench depth D1, the second trench has a second trench depth D2, and the third trench has a third trench depth D3. The depth of the dielectric area 56 is based on the second trench depth D2. The second trench depth D2 is less than the first trench depth D1 or the third trench depth D3. The first trench depth D1, the second trench depth D2 and the third trench depth D3 may be around 1-50 µm. In the present disclosure, the first trench depth D1 and the third trench depth D3 may be 6.0 µm and the second trench depth D2 may be 4.5 µm. The termination region TR may have a termination length L and the termination length L is determined by the structure of the dielectric area 36. The termination length L is around 1-200 µm. In the present disclosure, the termination length L may be 10 µm. The narrow termination length L is able to reduce the area needed for the termination region. Therefore, the material used for forming the device can be reduced, and the manufacturing cost can be reduced accordingly.

The present disclosure disclosed herein has been described by means of specific embodiments. However, numerous modifications, variations and enhancements can be made thereto without departing from the spirit and scope of the disclosure set forth in the claims.

What is claimed is:

1. A method of forming a power semiconductor device, the method comprising:
providing a semiconductor substrate, the semiconductor substrate having an active region and a termination region surrounding the active region;
disposing an epitaxial layer on the semiconductor substrate;
etching the epitaxial layer to form a first trench and a second trench, the first trench being disposed at the active region and a junction region between the active region and the termination region, and the second trench being disposed at the termination region, wherein a second trench width of the second trench is less than a first trench width of the first trench;
conducting an oxidation process to form a dielectric structure, the dielectric structure having a first dielectric layer disposed on the first trench and a dielectric area fully covering a trench area of the second trench.

2. The method of claim 1, further comprising:
disposing a shield electrode in a trench space formed by the first dielectric layer and etching the shield electrode at the active region;
conducting an oxide deposition to form a second dielectric layer covering the shield electrode;
etching the second dielectric layer at the active region and disposing a gate electrode on the first trench at the active region;
forming a doped region between the gate electrode;
conducting an oxide deposition to form a third dielectric layer covering the active region and the termination region;
forming a metal layer on the third dielectric layer, the metal layer contacting the doped region through a contact hole.

3. The method of claim 1, wherein the dielectric area has a pattern shape at bottom of the dielectric area and the pattern shape corresponds to a bottom shape of the second trench.

4. The method of claim 3, wherein the pattern shape comprises a continuous wave shape or a continuous ripple shape.

5. The method of claim 1, wherein the first trench width is around 1.2-1.5 µm and the second trench width is around 0.9-1.1 µm.

6. The method of claim 1, wherein the first trench has a first trench depth and the second trench has a second trench depth, the second trench depth is less than the first trench depth.

7. The method of claim 6, wherein the first trench depth and the second trench depth are around 1-50 µm.

8. The method of claim 1, wherein the termination region has a termination length and the termination length is around 1-200 µm.

9. The method of claim 1, the dielectric area comprises silicon dioxide.

10. The method of claim 2, the epitaxial layer is N-type lightly doped layer and the doped region is N-type highly doped region.

11. A method of forming a power semiconductor device, the method comprising:
providing a semiconductor substrate, the semiconductor substrate having an active region, a termination region adjacent to the active region and a trench ring region surrounding the active region and the termination region;
disposing an epitaxial layer on the semiconductor substrate;
etching the epitaxial layer to form a first trench, a second trench and a third trench, the first trench being disposed at the active region and a junction region between the active region and the termination region, the second trench being disposed at the termination region, and the third trench being disposed at the trench ring region, wherein a second trench width of the second trench is less than a first trench width of the first trench;
conducting an oxidation process to form a dielectric structure, the dielectric structure having a first dielectric layer disposed on the first trench and the third trench, and a dielectric area fully covering a trench area of the second trench.

12. The method of claim 11, further comprising:
disposing a shield electrode in a first trench space and a second trench space, the first trench space being formed by the first dielectric layer at the first trench and the second trench space being formed by the first dielectric layer at the third trench;
etching the shield electrode at the active region;
conducting an oxide deposition to form a second dielectric layer covering the shield electrode;
etching the second dielectric layer at the active region and disposing a gate electrode on the first trench at the active region;
forming a doped region between the gate electrode;
conducting an oxide deposition to form a third dielectric layer covering the active region, the termination region and the trench ring region;
forming a metal layer on the third dielectric layer, the metal layer contacting the doped region through a contact hole.

13. The method of claim 11, wherein the dielectric area has a pattern shape at bottom of the dielectric area and the pattern shape corresponds to a bottom shape of the second trench.

14. The method of claim 13, wherein the pattern shape comprises a continuous wave shape or a continuous ripple shape.

15. The method of claim 11, wherein the first trench width is around 1.2-1.5 µm and the second trench width is around 0.9-1.1 µm.

16. The method of claim 11, wherein a third trench width of the third trench is less than the first trench width, the third trench width is around 0.9-1.1 µm.

17. The method of claim 11, wherein the first trench has a first trench depth, the second trench has a second trench depth, and the third trench has a third trench depth, the second trench depth is less than the first trench depth or the third trench depth.

18. The method of claim 17, wherein the first trench depth and the third trench depth are around 1-50 µm.

19. The method of claim 1, wherein the termination region has a termination length and the termination length is around 1-200 µm.

20. The method of claim 1, the dielectric area comprises silicon dioxide.
